(19) United States
(12) Patent Application Publication
(10) Pub. No.: US 2026/0096153 A1
(43) Pub. Date: Apr. 2, 2026

(54) SEMICONDUCTOR STRUCTURE HAVING MULTILAYERED CHANNEL UNIT AND METHOD FOR MANUFACTURING THE SAME

(71) Applicant: Taiwan Semiconductor Manufacturing Company, Ltd., Hsinchu (TW)

(72) Inventors: Kuo-Chang CHIANG, Hsinchu (TW); Hsiao-Hua HUNG, Hsinchu (TW); Yu-Chuan SHIH, Hsinchu (TW); Yu-Jen CHIEN, Hsinchu (TW); Chih-Yu CHANG, Hsinchu (TW); Ming-Yen CHUANG, Hsinchu (TW)

(73) Assignee: Taiwan Semiconductor Manufacturing Company, Ltd., Hsinchu (TW)

(21) Appl. No.: 18/901,769

(22) Filed: Sep. 30, 2024

(51) Int. Cl. H01L 29/786; H01L 21/02; H01L 29/66

(52) U.S. Cl. CPC H10D 30/6757; H10D 30/031; H10D 30/6755; H10P 14/6548

(57) ABSTRACT

A method for manufacturing a semiconductor structure includes: forming a gate electrode; forming a gate dielectric; forming a channel unit on the gate dielectric opposite to the gate electrode, the channel unit including: a lower channel layer including a first composition that is uniform throughout the lower channel layer, the lower channel layer having a first band gap; and an upper channel layer including a second composition that is different from the first composition and that is uniform throughout the upper channel layer, the upper channel layer having a second band gap greater than the first band gap; and forming a source electrode and a drain electrode that are electrically connected to the lower channel layer, and that are spaced apart from each other.

### BACKGROUND

Field-effect transistor (FET) with a channel made of metal oxides has advantageous effects such as a high switching current ratio, and a low off current, implying that such FET may have a low power consumption with a low electric field control. In addition, such FET may be manufactured at a relatively low temperature (e.g., less than about 400° C.), and is widely employed in a back-end-of-line process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 17 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

A thin film transistor generally has a gate electrode, a source electrode, a drain electrode, a gate dielectric, and a channel. The thin film transistor is switched on/off by the gate electrode to control charge conduction between the source electrode and the drain electrode through the channel, in which the source electrode and the drain electrode are located on a same horizontal level and are spaced apart from each other by the channel. The channel may be made of an oxide-based semiconductor material (e.g., a metal oxide, but is not limited thereto) that has a relatively low band gap, and that has many defects therein known as oxygen vacancies. The oxygen vacancies easily adsorb electrons, and are prone to react with surrounding layers (e.g., a cap layer that is disposed on the channel, and an interlayer dielectric, but are not limited thereto). The reaction between the oxygen vacancies and the surrounding layers may include absorption of water and hydrogen, but are not limited thereto, may induce additional carrier (e.g., electron) transfer, and thus a high carrier concentrations, thereby resulting in the thin film transistor having a poor device stability. In addition, the channel is in contact with the gate dielectric which has a high charge trap density, i.e., many acceptor-like traps are present in the gate dielectric, especially at an interface between the channel and the gate dielectric. The traps attract electrons from the channel, and induce even more electron transfer, and thus higher carrier concentration at the interface. In addition, the traps may undesirably cause electron flowing from the channel to the gate dielectric in a vertical direction, and results in speed degradation of the thin film transistor. It is desirable that the electrons flow within the channel in a horizontal direction to achieve fast conduction between the source electrode and the drain electrode. Moreover, when the thin film transistor is formed with a relatively small size, short channel effect may be observed due to the charge carriers (e.g., electrons) being undesirably trapped in the gate dielectric.

The present disclosure is directed to a semiconductor structure having a multi-layered channel unit, and a method for manufacturing the same. The semiconductor structure may be a thin film transistor, but is not limited thereto. Other suitable applications of the semiconductor structure are within the contemplated scope of the present disclosure. The semiconductor structure of the present disclosure includes a gate electrode, a source electrode, a drain electrode, a gate dielectric, and a channel unit. The source electrode and the drain electrode are electrically connected to each other through the channel unit. The channel unit is electrically controlled by the gate electrode and is insulated from the gate electrode by the gate dielectric. The channel unit includes multiple channel layers that have different band gaps, different compositions and different thicknesses. A main channel layer of the channel unit has a band gap that is lower than those of the other channel layer(s), so that charge conduction is confined within the main channel layer to ensure that the semiconductor structure has a high speed and good device stability. By adjusting the thicknesses and compositions of each of the channel layers, carrier concentration and carrier distribution are highly flexible and may be adjusted to reach a balance between desired mobility and reliability of the semiconductor structure.

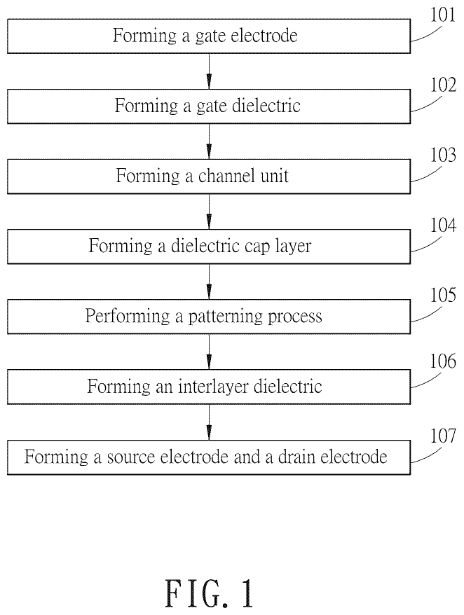

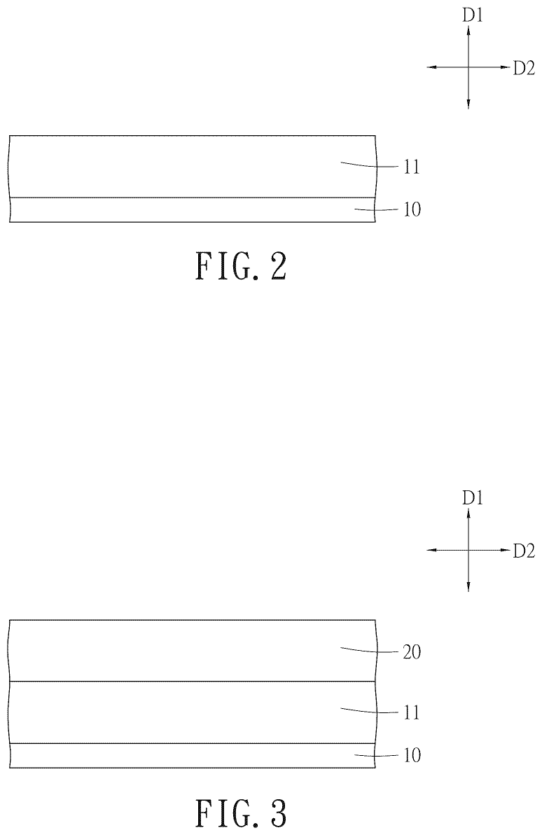

FIG. 1 is a flow diagram illustrating a method for manufacturing the semiconductor structure (for example, the semiconductor structure shown in FIG. 9) in accordance with some embodiments. FIGS. 2 to 9 illustrate schematic views of intermediate stages of the method in accordance with some embodiments. Some repeating structures are omitted in FIGS. 2 to 9 for the sake of brevity. Additional steps can be provided before, after or during the method, and some of the steps described herein may be replaced by other steps or be eliminated.

Referring to FIG. 1 and the example illustrated in FIG. 2, the method begins at step 101, where a gate electrode 11 is formed on a base structure 10.

In some embodiments, the base structure 10 may include multiple elements (not shown), for example, a front-end-of-line (FEOL) section and a back-end-of-line (BEOL) section formed on the FEOL section. The FEOL section may include a substrate, a device, lower dielectric portion, and lower conductive features formed in the lower dielectric portion. The BEOL section may include an upper dielectric portion and upper conductive features formed the upper dielectric portion.

In some embodiments, the substrate may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The material for forming the substrate may be doped with p-type impurities or n-type impurities, or undoped. In addition, the substrate may be a bulk silicon substrate, a silicon-on-insulator (SOI) substrate, or a germanium-on-insulator (GOI) substrate. Other suitable materials for the substrate are within the contemplated scope of disclosure.

In some embodiments, the device may be planar transistors, fin-type field-effect transistors (FinFET), nanosheet semiconductor devices (e.g. gate-all-around field-effect transistors (GAAFET), forksheet field-effect transistors, complementary field-effect transistors (CFET), or the like), capacitors, resistors, decoders, amplifiers, other suitable devices, and combinations thereof. Each of the lower conductive features may be a contact, e.g., a gate contact, a source/drain contact, or other suitable elements for the device.

In some embodiments, each of the lower and upper dielectric portions may include a dielectric material, such as silicon oxide, silicon oxynitride, silicon nitride, a high-k dielectric, other suitable materials, or combinations thereof; and each of the lower and upper conductive features may include an electrically conductive materials, such as copper, cobalt, tungsten, ruthenium, other suitable materials, or combinations thereof.

The gate electrode 11 is electrically connected to a word line, which is not shown in the figures. In some embodiments, the word line may be one of the upper conductive features, and may be connected to the device through some of the upper and lower conductive features. In some embodiments, the gate electrode 11 includes an electrically conductive material, such as a metal, a metal nitride, a metal carbide, or other materials that are compatible with a back-end-of-line process (e.g., that can be prepared with a process less than approximately 400° C.). Examples of the metal are copper, aluminum, titanium, tantalum, cobalt, tungsten, gold, platinum, nickel, iridium, palladium, rhodium, ruthenium, osmium, molybdenum, or the likes, or combinations thereof. Examples of the metal nitride is titanium nitride, tantalum nitride, or the likes, or combinations thereof. In certain embodiments, the gate electrode 11 has a thickness ranging from about 50 Å to about 500 Å, but is not limited thereto. Other suitable materials and/or thickness ranges for the gate electrode 11 are within the contemplated scope of the present disclosure.

Referring to FIG. 1 and the example illustrated in FIG. 3, the method proceeds to step 102, where a gate dielectric 20 is formed on the gate electrode 11.

The gate dielectric 20 is configured to insulate the gate electrode 11 from a channel unit 30 (see FIG. 9, which will be formed in subsequent step). The gate dielectric 20 may include a suitable dielectric material, such as a high dielectric constant (high-k) material. Examples of the high-k material are zirconium dioxide (ZrO₂), hafnium oxide (HfO₂), hafnium titanium oxide (HfTiO), hafnium lanthanum oxide (HfLaO), hafnium silicon oxide (HfSiO), hafnium zirconium oxide (HfZrO). In other embodiments, the gate dielectric 20 may include a material that has memory behavior. The gate dielectric 20 may have a thickness ranging from about 30 Å to about 150 Å, but is not limited thereto. Other suitable materials and/or thickness ranges for the gate dielectric 20 are within the contemplated scope of the present disclosure.

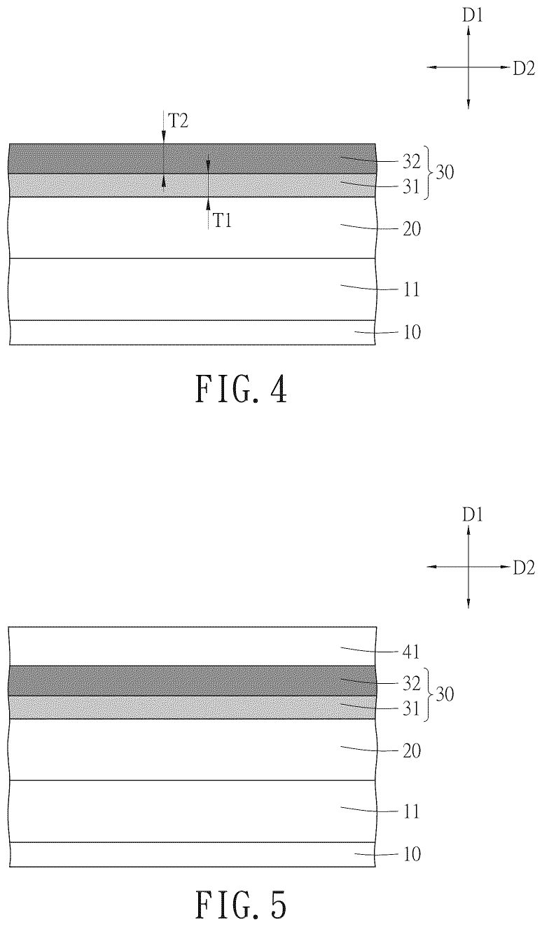

Referring to FIG. 1 and the example illustrated in FIG. 4, the method proceeds to step 103, where a channel unit 30 is formed on the gate dielectric 20 opposite to the gate electrode 11.

The channel unit 30 is controlled by the gate electrode 11, so as to control current flow between a source electrode 12 (see FIG. 9) and a drain electrode 13 of the semiconductor structure. Ideally, when no voltage is applied to the gate electrode 11, the semiconductor structure is kept normally off, and there is no current flow (or known as a leakage current) between the source electrode 12 and the drain electrode 13. That is, the semiconductor structure of the present disclosure may have a threshold voltage (Vₜ) greater than 0 V. In addition, the semiconductor structure of the present disclosure may have a voltage shift (ΔVₜ) ranging from about −100 mV to about +100 mV when a stress bias ranging from about −2 V to +2 V is applied at about room temperature, or at other suitable temperature.

In order to achieve the electrical properties as described above, the channel unit 30 of the semiconductor structure may have a relatively high band gap, such as ranging from about 3 eV to about 5 eV, or from about 3.5 eV to about 4.5 eV, so that the channel unit 30 can be better controlled though the gate electrode 11 to avoid a leakage current between the source electrode 12 and the drain electrode 13. If the band gap is too high (e.g., greater than about 5 eV), the channel unit 30 may be too insulating and lose the function of serving as a channel of the semiconductor structure. If the band gap is too low (e.g., less than about 3 eV), the channel unit 30 may be too conducting, which unfavors control of the channel unit 30 by the gate electrode 11, and may result in the leakage current between the source electrode 12 and the drain electrode 13.

In some embodiments, the channel unit 30 has a multi-layered structure. For instance, referring to FIG. 4, the channel unit 30 may include two channel layers, namely a lower channel layer 31, and an upper channel layer 32. In a vertical direction D1, the lower channel layer 31 is disposed on the gate dielectric 20 opposite to the gate electrode 11, and the upper channel layer 32 is disposed on the lower channel layer 31 opposite to the gate electrode 11.

The lower channel layer 31 is configured as a main channel layer of the channel unit 30. That is, the lower channel layer 31 facilitates horizontal conduction of charge carriers between the source electrode 12 and the drain electrode 13 when the semiconductor structure is switched on (i.e., the semiconductor structure is in operation), and avoids leakage current between the source electrode 12 and the drain electrode 13 when the semiconductor structure is switched off. Therefore, the lower channel layer 31 is located more proximal to the gate electrode 11 than the upper channel layer 32 so as to be better controlled by the gate electrode 11. In addition, the lower channel layer 31 is more conducting and bears a higher carrier (e.g. electron) concentration in comparison with the upper channel layer 32. Such lower channel layer 31 includes or is made of a first composition, and has a first band gap. In some embodiments, the first composition includes or consists of a first metal oxide that has a relatively low band gap, such as not greater than approximately 4 eV, but is not limited thereto. Examples of the first metal oxide are indium oxide (In₂O₃, with a band gap of about 2.8 eV), zinc oxide (ZnO, with a band gap of about 3.4 eV), tin oxide (SnO₂, with a band gap of about 3.6 eV), cadmium oxide (CdO, with a band gap of about 2.5 eV), titanium oxide (TiO), silver oxide (Ag₂O), cerium oxide (CeO₂), or the likes, or combinations thereof, but are not limited thereto. Other suitable materials for forming the lower channel layer 31 are within the contemplated scope of the present disclosure.

The upper channel layer 32 serves as an electron barrier to confine conduction of charge carrier (e.g., electrons) close to the gate electrode 11 and ideally in a horizontal direction D2 transverse to (e.g., perpendicular to) the vertical direction D1, but not in the vertical direction D1 to reach an upper side of the channel unit 30 that is far from the gate electrode 11. The upper channel layer 32 is less conducting and bears a lower carrier (e.g. electron) concentration in comparison with the lower channel layer 31. The upper channel layer 32 includes or is made of a second composition, and has a second band gap, wherein the second composition is different from the first composition, and the second band gap is greater than the first band gap. In some embodiments, the second composition includes or consists of a second metal oxide that has a relatively high band gap, such as greater than approximately 4 eV, but is not limited thereto. Examples of the second metal oxide are gallium oxide (Ga₂O₃, with a band gap of about 4.8 eV), aluminum oxide (Al₂O₃, with a band gap of about 6.4 eV), germanium dioxide (GeO₂, with a band gap of about 5.7 eV), tungsten oxide (WO₃), scandium oxide (Sc₂O₃, with a band gap of about 5.3 eV), lanthanum oxide (La₂O₃, with a band gap of about 5.7 eV), lutetium oxide (Lu₂O₃, with a band gap of about 5.7 eV), or the likes, or combinations thereof, but are not limited thereto. Other suitable materials for forming the upper channel layer 32 are within the contemplated scope of the present disclosure. In other embodiments, the second composition is free of the aforementioned first metal oxide of the first composition.

Due to the high band gap property of the second composition of the upper channel layer 32, even if the upper channel layer 32 adsorbs electrons, it will be difficult for the electrons to reach the conduction band, and thus the upper channel layer 32 can effectively reduce electron conduction in the vertical direction D1 to reach the upper side of the channel unit 30 and can reduce or avoid leakage current between the source electrode 12 and the drain electrode 13 when the semiconductor structure is switched off. In addition, the high band gap second metal oxide has a bonding comparatively stronger than that of the low band gap first metal oxide (i.e., in the second metal oxide, a bonding force between metal atoms and oxygen atoms is relatively stronger than a bonding force therebetween in the first metal oxide), and thus the second metal oxide is less likely to decompose or generate oxygen vacancies. Moreover, the second metal oxide generally has less defects, i.e., fewer oxygen vacancies to adsorb electrons in comparison with the first metal oxide. As such, reaction (e.g., adsorption of water or hydrogen) between the upper channel layer 32 and surrounding layers (e.g., a dielectric cap layer 41 and an interlayer dielectric 42 as shown in FIG. 9, but is not limited thereto) is suppressed, so as to minimize electron transfer (or known as electron trap/detrap behavior between the upper channel layer 32 and surrounding layers) and reduce carrier concentration, thereby improving device stability and reliability of the semiconductor structure.

It is noted that, the structure of different layers of the channel unit 30, e.g., the lower channel layer 31 and the upper channel layer 32 may be confirmed by conducting TEM imaging of a cross sectional view of the channel unit 30 along the vertical direction D1 and observing a clear heterointerface present between the two adjacent layers. Such clear interface indicates the absence of interdiffusion of material(s) between the two adjacent layers, and that compositions of the lower channel layer 31 and the upper channel layer 32 are clearly different from each other. In some embodiments, the first composition is uniform throughout the lower channel layer 31, and the second composition is uniform throughout the upper channel layer 32, especially in the vertical direction D1. For instance, when the first composition consists of one or more different types of the first metal oxides, the type(s) of the first metal oxides, and atomic percentage(s) of the type(s) of the first metal oxide(s) at an upper portion of the lower channel layer 31 (e.g., proximal to the upper channel layer 32) are respectively the same as the type(s) of the first metal oxide(s) and the atomic percentage(s) of the type(s) of the first metal oxide(s) at a lower portion of the lower channel layer 31 (e.g., proximal to the gate dielectric 20). In other words, both the upper portion and the lower portion of the lower channel layer 31 have the same type(s) of the first metal oxide(s), and with the same distribution (e.g., atomic percentage(s)) of the type(s) of the first metal oxide(s). Similar to the lower channel layer 31, in the upper channel layer 32, both an upper portion and a lower portion of the upper channel layer 32 have the same type(s) of the second metal oxide(s), and with the same distribution (e.g., atomic percentage(s)) of the type(s) of the second metal oxide(s). In some cases, even if a conducting metal oxide (e.g., the first metal oxide) is present in both the lower and upper channel layers 31, 32, the conducting metal oxide has, along the vertical direction D1, a constant atomic percentage in the upper channel layer 32 and another constant atomic percentage in the lower channel layer 31, but does not exhibit a gradient distribution (e.g., a gradient atomic percentage of the conducting metal oxide) across the upper channel layer 32 and the lower channel layer 31 in the vertical direction D1. It is noted that the gradient distribution of the conducting metal oxide in the vertical direction D1 indicates that charge carriers (e.g., electron) fail to concentrate at a lower side of the channel unit 30 (which is close to and better controlled by the gate electrode 11), and are present at the upper side of the channel unit 30 (which is far from, and less controlled by the gate electrode 11). As a result, speed degradation may occur in the semiconductor structure, and leakage current may also occur between the source and drain electrodes 12, 13.

It is noted that, in some embodiments, a band gap difference between the second band gap and the first band gap is not greater than approximately 0.5 eV and is greater than 0 eV, such as ranging from about 0.1 eV to about 0.5 eV, or from about 0.1 eV to about 0.3 eV, or from about 0.3 eV to about 0.5 eV. If the band gap difference is too large, e.g., greater than approximately 0.5 eV, a band bending of the conduction bands of the lower channel layer 31 and the upper channel layer 32 may be induced, which would be analogous to an intermediate channel layer being inserted between the upper and lower channel layers 32, 31, and which would result in the undesirable effect of the conducting first metal oxide having a gradient distribution in the vertical direction D1. If the band gap difference is too small (e.g., smaller than about 0.1 eV) or is equal to 0 eV, the effect of the charge carrier (e.g., electrons) being confined within the lower channel layer 31 in the horizontal direction D2 may not be achieved.

In certain embodiments, the lower channel layer 31 is formed with a first thickness (T1), and the upper channel layer 32 is formed with a second thickness (T2). In addition, it is noted that the second thickness (T2) is greater than the first thickness (T1), so as to ensure that the switching on/off of the lower channel layer 31 is well controlled by the gate electrode 11. Since the first composition of the lower channel layer 31 is relatively conducting and bears a higher density of charge carriers, if the lower channel 31 is too thick, the gate electrode 11 may not well control charge carriers that are distal from the gate electrode 11 and may result in leakage current between the source electrode 12 and the drain electrode 13. In some embodiments, each of the second thickness (T2) and the first thickness (T1) is not greater than about 10 nm and is greater than about 0.5 nm. The lower and upper channel layers 31, 32 are formed with such range so as to allow easy detection and identification thereof and to ensure proper functions thereof without additional and unnecessary production cost. Other suitable thickness ranges for each of the lower and upper channel layers 31, 32 are within the contemplated scope of disclosure.

The band gap of the channel unit 30 may be altered by varying amount and types of metal oxides present in each of the lower and upper channel layers 31, 32, as well as thickness of each of the lower and upper channel layers 31, 32. The following equation demonstrates calculation of a band gap of an arbitrary one of the channel years 31, 32 (which is referred to as “arbitrary channel layer” in this paragraph). In an exemplary example, a composition of the arbitrary channel layer has exemplarily n types of metal oxide. The band gap energy (denoted as E) of the arbitrary channel layer may be calculated using the following Equation (I).

$$E = {\sum }_{i = 1}^{n} {E}_{i} = {E}_{1} \times {A}_{1} + {E}_{2} \times {A}_{2} + … + {E}_{n} \times {A}_{n} \qquad ( I )$$

In Equation (I), Eₙ (e.g., E₁, E₂, . . . , Eₙ as illustrated above) represents a band gap energy of one of the different types of metal oxides present in the composition, and Aₙ (e.g., A₁, A₂, . . . , Aₙ as illustrated above) represents an atomic percentage of the one type of the metal oxides present in the composition out of a total of 100 atomic percentage of all of the metal oxides in the composition. For instance, when three types of metal oxides are included, a first type of the metal oxide in the composition may have a band gap of E₁ and an atomic percentage of A₁; a second type of metal oxide in the composition may have a band gap of E₂ and an atomic percentage of A₂; and a third type of metal oxide in the composition may have a band gap of E₃ and an atomic percentage of A₃. In other embodiments, there may be less than three or more than three types of metal oxides, and Equation (I) may be adjusted accordingly by summing up the product of Eₙ×Aₙ for each type of the metal oxides present in the composition.

As such, the band gap of each of the lower channel layer 31 (denoted as E_{lower}) and the upper channel layer 32 (denoted as Eᵤₚₚₑᵣ) may be determined. The band gap of the channel unit 30 (denoted as E_{channel}) may be obtained using the following Equation (II), wherein T1 and T2 represent thickness of the lower channel layer 31 and thickness of the upper channel layer 32, respectively, as aforementioned.

$${E}_{channel} = {E}_{lower} \times \frac{T 1}{T 1 + T 2} + {E}_{upper} \times \frac{T 2}{T 1 + T 2} \qquad ( II )$$

Based on Equations (I) and (II), it is noted that the band gap of the channel unit 30 can be altered by adjusting composition (types and amounts) of the metal oxides that are present in each of the lower and upper channel layers 31, 32, as well as adjusting thickness of each of the lower and upper channel layers 31, 32.

The channel unit 30 may be formed by sequentially forming the lower channel layer 31 and the upper channel layer 32 on the gate dielectric 20 in a vertical direction D1. That is, the upper channel layer 32 is disposed on the lower channel layer 31 opposite to the gate dielectric 20 and the gate electrode 11. By altering composition and thickness of each of the lower and upper channel layers 31, 32, the desired band gap of the channel unit 30 may be obtained, so as to reach an improved performance, or electrical properties of the semiconductor structure. Each of the lower channel layer 31 and the upper channel layer 32 may be formed by any suitable processes, such as physical vapor deposition (PVD), chemical vapor deposition (CVD), atomic layer deposition (ALD), pulsed laser deposition (PLD), metal doping, metal oxidation, or the likes, or combinations thereof, but are not limited thereto. The lower channel layer 31 and the upper channel layer 32 may be formed in in-situ manner (using the same process), or ex-situ manner (using different processes). Other suitable processes for forming the lower and upper channel layers 31, 32 are within the contemplated scope of the present disclosure.

Referring to FIG. 1 and the example illustrated in FIG. 5, the method proceeds to step 104, where a dielectric cap layer 41 is formed on the channel unit 30 opposite to the gate dielectric 20.

The dielectric cap layer 41 is configured to protect upper surface of the channel unit 30 from any damages in any processes during subsequent step 105. In some embodiments, the dielectric cap layer 41 includes or is made of a dielectric material. Examples of the dielectric material are silicon oxide, or a high-k dielectric, such as hafnium oxide (HfO₂), aluminum oxide (Al₂O₃), titanium oxide (TiO₂), or the likes, or combinations thereof, but are not limited thereto. The dielectric cap layer 41 may be formed with a thickness ranging from about 10 Å to about 200 Å. Other suitable materials and/or thickness ranges for the dielectric cap layer 41 are within the contemplated scope of the present disclosure.

In some embodiments, step 104 may include a first sub-step of depositing a material layer for forming the dielectric cap layer 41, followed by a second sub-step of subjecting the material layer to a treatment so as to refine and form the material layer into the dielectric cap layer 41 with a desired quality. In some embodiments, the treatment in the second sub-step is an oxygen treatment. In other embodiments, the treatment is a plasma treatment. Other suitable processes for forming the dielectric cap layer 41 are within the contemplated scope of the present disclosure.

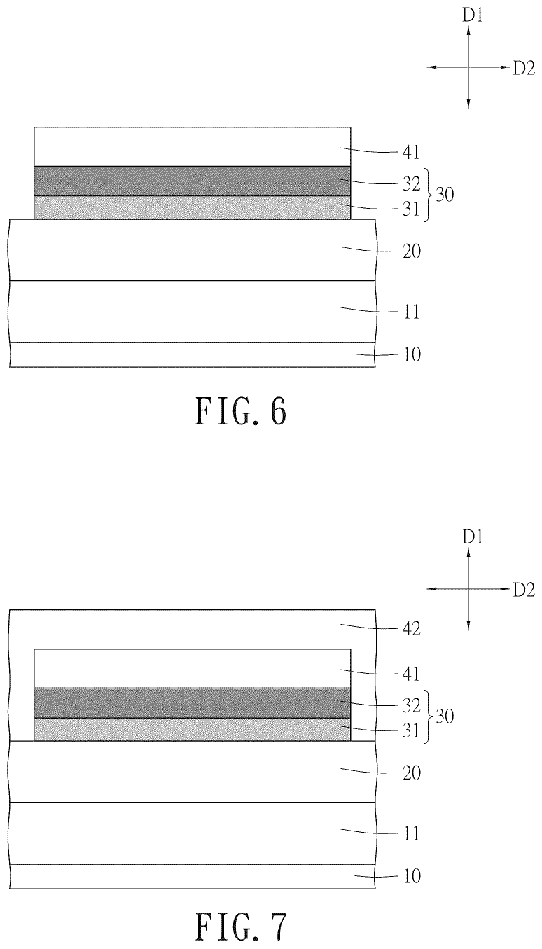

Referring to FIG. 1 and the example illustrated in FIG. 6, the method proceeds to step 105, where a patterning process is performing to pattern a stack of the channel unit 30 and the dielectric cap layer 41 as shown in FIG. 5

Step 105 may adopt any suitable patterning processes known in the art. After step 105, the stack of the channel unit and the dielectric cap layer 41 is patterned into individual stack portions, each of which includes a portion of the dielectric cap layer 41 and a corresponding portion of the channel unit 30. In FIG. 6 and subsequent figures, only one of the individual stack portions is shown and described. Hereinafter, the portion of the patterned cap layer is referred to as the dielectric cap layer 41, and the corresponding portion of the channel unit 30 is referred to as the channel unit 30.

Referring to FIG. 1 and the example illustrated in FIG. 7, the method proceeds to step 106, where an interlayer dielectric (ILD) 42 is formed.

The ILD 42 is formed over a top surface and a side surface of the individual stack portion. That is, a top surface and a side surface of the dielectric cap layer 41, and a side surface of the channel unit 30 are covered and enclosed by the ILD 42. The ILD 42 may include a dielectric material, such as silicon oxide, silicon oxynitride, silicon nitride, a high-k dielectric, or the likes, or combinations thereof, but are not limited thereto. In some embodiments, the ILD 42 is formed with a thickness ranging from about 50 Å to about 500 Å, but is not limited thereto. Other suitable materials and/or thickness ranges for the ILD 42 are within the contemplated scope of the present disclosure.

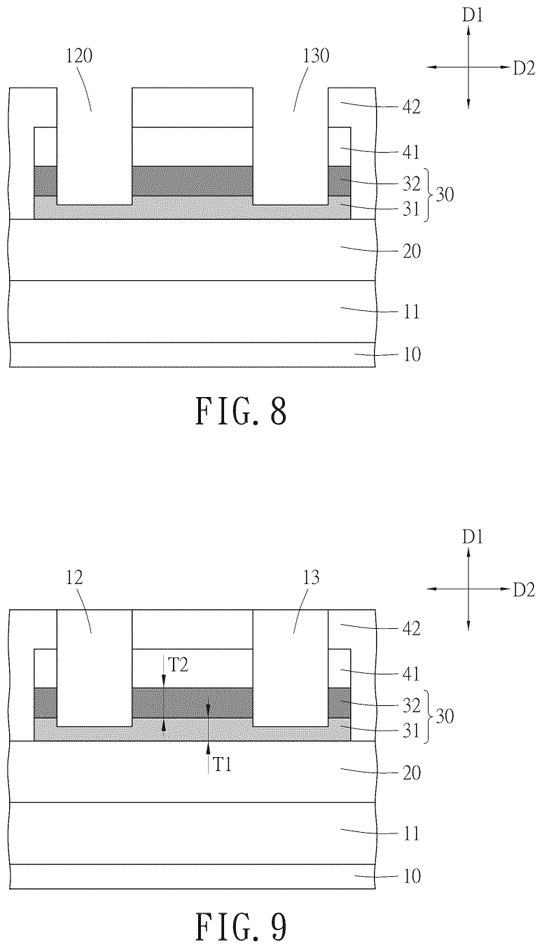

Referring to FIG. 1 and the examples illustrated in FIGS. 8 and 9, the method proceeds to step 107, where a source electrode 12 and a drain electrode 13 are formed.

Referring to FIG. 8, step 107 may include a first sub-step of forming trenches 120 and 130 which are to accommodate the source electrode 12 and the drain electrode 13, respectively. The trenches 120, 130 may be formed using any suitable patterning process, such as an etching process, but is not limited thereto. The trenches 120, 130 may extend from a top surface of the ILD 42 and terminate at the channel unit 30. For instance, the trenches 120, 130 may each terminate at the lower channel layer 31 of the channel unit 30. In other embodiments, the trenches 120, 130 may terminate the upper channel layer 32. The trenches 120, 130 may be formed to be spaced apart from each other by a distance ranging from about 1 nm to about 100 nm, but is not limited thereto. Such distance may also be known as a gate length (L_{g}), or an effective channel length of the semiconductor structure shown in FIG. 9. Other suitable processes for forming the trenches 120, 130 and other suitable ranges of the gate length are within the contemplated scope of the present disclosure.

Referring to FIG. 9 step 107 may further include a second sub-step of forming the source electrode 12 and the drain electrode 13 respectively in the trenches 120, 130.

The source electrode 12 and the drain electrode 13 may be located at a same horizontal level, and are spaced apart from each other in the horizontal direction. Each of the source electrode 12 and the drain electrode 13 is formed to extend through the dielectric cap layer 41 and the upper channel layer 32 in the vertical direction (D1) so as to be electrically connected to the lower channel layer 31. In addition, the source electrode 12 and the drain electrode 13 are electrically connected to a source line and a bit line that are not shown in FIG. 9, respectively. The source line and the bit line may be respectively located above the source electrode 12, and the drain electrode 13, opposite to the gate electrode 11. Each of the source electrode 12 and the drain electrode 13 may include a material similar to that of the gate electrode 11, and a thickness range similar to that of the gate electrode 11. Therefore, details thereof are omitted for the sake of brevity.

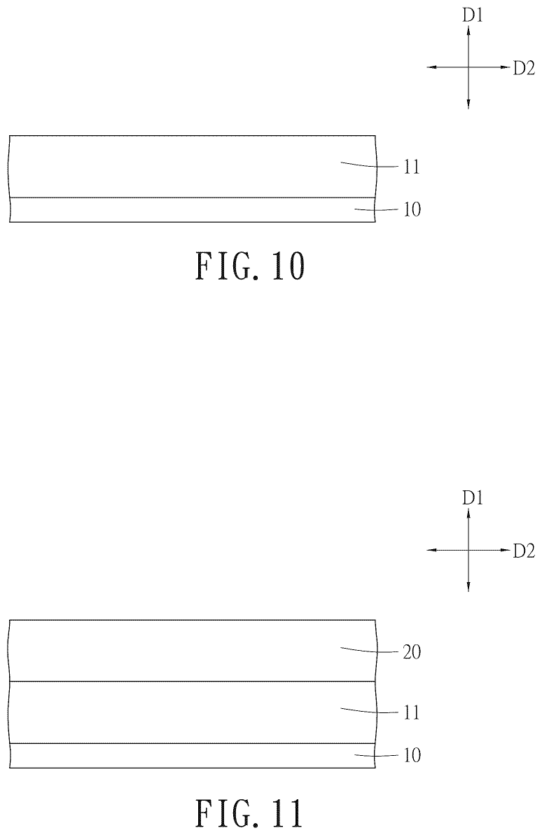

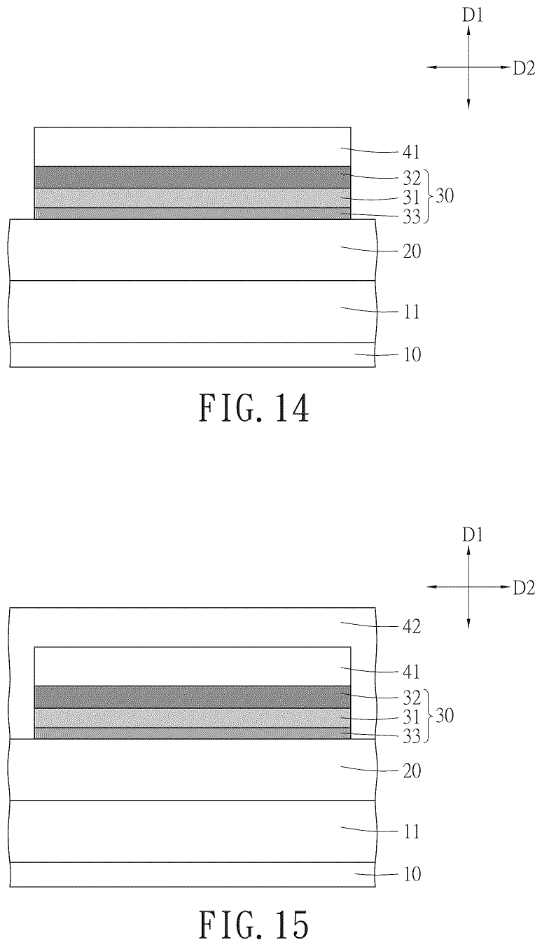

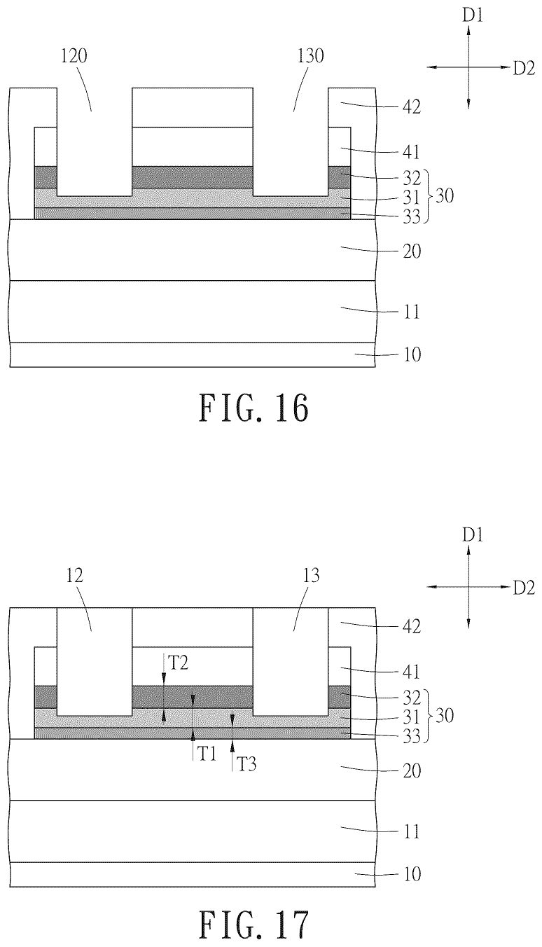

After step 107, the semiconductor structure of the present disclosure is obtained. In the semiconductor structure shown in FIG. 9, the lower channel layer 31 of the channel unit 30 is adjacent to the gate dielectric 20. In accordance with some embodiments of the present disclosure, in order to avoid interaction between the channel unit 30 and the gate dielectric 20, and to better confine electron transfer within the channel unit 30, the channel unit 30 of the semiconductor structure shown in FIG. 17 may further include a protective channel layer 33 between the lower channel layer 31 and the gate dielectric 20. The semiconductor structure shown in FIG. 17 may be prepared using steps described in FIG. 1, and FIGS. 10 to 17 illustrate schematic views of intermediate stages of the method in accordance with some embodiments. Some repeating structures are omitted in FIGS. 10 to 17 for the sake of brevity. Additional steps can be provided before, after or during the method, and some of the steps described herein may be replaced by other steps or be eliminated. Steps 101, 102, 104 to 107 illustrated in FIGS. 10, 11, 13 to 17 are respectively similar to FIGS. 2, 3, 5 to 9 and descriptions thereof, and thus the details are omitted for the sake of brevity. The paragraphs merely focus on step 103, which regards to details of formation of the different layers of the channel unit 30.

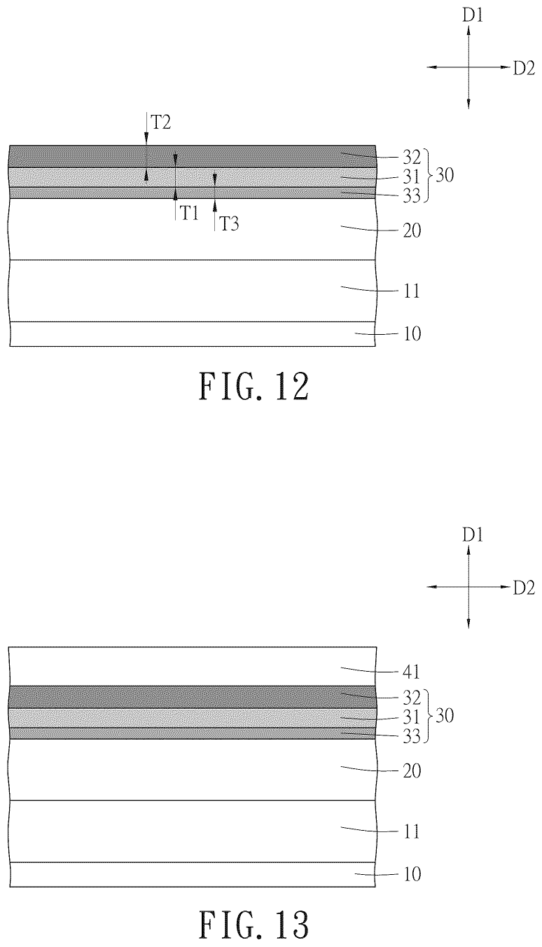

Referring to FIG. 12, in step 103, the channel unit 30 further includes the protective channel layer 33, in addition to the lower channel layer 31 and the upper channel layer 32 as described with reference to FIG. 5. Details regarding the lower and upper channel layers 31, 32 are omitted for the sake of brevity.

Specifically, the protective channel layer 33 is formed on the gate dielectric 20 prior to formation of the lower channel layer 31 and the upper channel layer 32. The protective channel layer 33 has a third composition and a third band gap. The protective channel layer 33 is configured to protect the lower channel layer 31, so as to minimize interaction between the lower channel layer 31 and the gate dielectric 20. To achieve such effect, the protective channel layer 33 has the third band gap greater than the first band gap of the lower channel layer 31, and the third composition is different from the first composition. In some embodiments, the third band gap is greater than the first band gap by not greater than approximately 0.5 eV. In some embodiments, the third composition includes or consists of the second metal oxide (of the upper channel layer 32) that has the relatively high band gap, e.g., greater than approximately 4 eV, but is not limited thereto. Examples of the second metal oxide have been described and are not repeated hereinafter. Please note that the types and amounts of the second metal oxide present in the upper channel layer 32 and the protective channel layer 33 may be the same or different from each other.

By inserting the protective channel layer 33 between the lower channel layer 31 and the gate dielectric 20, any traps present in the gate dielectric 20 or at an interface between the gate dielectric 20 and the protective channel layer 33 is less likely to interact with and affect the lower channel layer 31. In addition, the protective channel layer 33, due to the high band gap property thereof, serves as another electron barrier to confine any charge carriers in the lower channel layer 31 such that the charge carriers are transmitted horizontally between the source electrode 12 and the drain electrode 13 instead of being transmitted in the vertical direction D1 to reach the gate dielectric 20. Moreover, the second metal oxide generally has less defects i.e., fewer oxygen vacancies than the first metal oxide, which also favors suppression of interaction between the channel unit 30 and the gate dielectric 20, so as to minimize electron transfer (or known as electron trap/detrap behavior) and reduce carrier concentration, thereby improving device stability and reliability of the semiconductor structure.

It is noted that the protective channel layer 33 has a third thickness (T3) that is smaller than the first thickness (T1) and that ranges from about 0.5 nm to about 10 nm in accordance with some embodiments. Despite the insertion of the protective channel layer 33 might impact control of the lower channel layer 31 from the gate electrode 11, a relatively small thickness of the protective channel layer 33 could minimize loss of control of the lower channel layer 31 from the gate electrode 11 by having the lower channel layer 31 to be as close as possible to the gate electrode 11. Conceivably, the benefits of having the protective channel layer 33 as described in the previous paragraph outweigh drawbacks thereof.

The embodiments of the present disclosure have the following advantageous features. The channel unit 30 includes multiple channel layers that have different compositions, different band gaps and different thicknesses, so as to confine conduction of charge carriers within the lower channel layer 31 (which serves as the main channel), while interactions between the lower channel layer 31 and surrounding layers (e.g., the dielectric cap layer 41, the ILD 42, or the gate dielectric 20) are suppressed to effectively reduce generation of oxygen deficiencies and electron transfer. As such, the gate electrode 11 can have better control to the lower channel layer 31, and current leakage between the source electrode 12 and the drain electrode 13 is minimized, so as to improve stability, reliability and performance (e.g. improved speed) of the semiconductor structure.

In accordance with some embodiments of the present disclosure, a method for manufacturing a semiconductor structure includes: forming a gate electrode; forming a gate dielectric; forming a channel unit on the gate dielectric opposite to the gate electrode, the channel unit including: a lower channel layer including a first composition that is uniform throughout the lower channel layer, the lower channel layer having a first band gap; and an upper channel layer including a second composition that is different from the first composition and that is uniform throughout the upper channel layer, the upper channel layer having a second band gap greater than the first band gap; and forming a source electrode and a drain electrode that are electrically connected to the lower channel layer, and that are spaced apart from each other.

In accordance with some embodiments of the present disclosure, the first composition includes a first metal oxide that has a band gap not greater than 4 eV.

In accordance with some embodiments of the present disclosure, the second composition is free of the first metal oxide.

In accordance with some embodiments of the present disclosure, the second composition includes a second metal oxide with a band gap greater than 4 eV.

In accordance with some embodiments of the present disclosure, forming the channel unit further includes forming a protective channel layer on the gate dielectric prior to forming the lower channel layer and the upper channel layer, the protective channel layer including a third composition that is different from the first composition and that is uniform throughout the protective channel layer.

In accordance with some embodiments of the present disclosure, the third composition includes a third metal oxide with a band gap greater than 4 eV.

In accordance with some embodiments of the present disclosure, a thickness of the protective channel layer is smaller than a thickness of the lower channel layer.

In accordance with some embodiments of the present disclosure, the thickness of the protective channel layer is greater than 0.5 nm.

In accordance with some embodiments of the present disclosure, the second band gap is greater than the first band gap by not greater than 0.5 eV.

In accordance with some embodiments of the present disclosure, a thickness of the upper channel layer is greater than a thickness of the lower channel layer.

In accordance with some embodiments of the present disclosure, a method for manufacturing a semiconductor structure includes: forming a gate electrode; forming a gate dielectric; forming a channel unit, the channel unit including a lower channel layer and an upper channel layer that are sequentially formed on the gate dielectric along a vertical direction in a manner that: the lower channel layer has a first composition which is uniform along the vertical direction, the upper channel layer has a second composition which is different from the first composition and which is uniform along the vertical direction, and a band gap of the upper channel layer is greater than a band gap of the lower channel layer; and forming a source electrode and a drain electrode that are electrically connected to the lower channel layer, and that are spaced apart from each other.

In accordance with some embodiments of the present disclosure, forming the channel unit further includes forming a protective channel layer on the gate dielectric opposite to the gate electrode prior to forming the lower channel layer and the upper channel layer, the protective channel layer having a third composition which is different from the first composition and which is uniform along the vertical direction, a band gap of the protective channel layer being greater than the band gap of the lower channel layer.

In accordance with some embodiments of the present disclosure, a band gap difference between the upper channel layer and the lower channel layer is not greater than 0.5 eV, and a band gap difference between the lower channel layer and the protective channel layer is not greater than 0.5 eV.

In accordance with some embodiments of the present disclosure, a thickness of the upper channel layer is greater than a thickness of the lower channel layer, and the thickness of the lower channel layer is greater than a thickness of the protective channel layer.

In accordance with some embodiments of the present disclosure, the method further includes forming a dielectric cap layer on the channel unit opposite to the gate dielectric.

In accordance with some embodiments of the present disclosure, an oxygen treatment is performed during forming the dielectric cap layer.

In accordance with some embodiments of the present disclosure, a plasma treatment is performed during forming the dielectric cap layer.

In accordance with some embodiments of the present disclosure, each of the source electrode and the drain electrode is formed to extend through the dielectric cap layer and the upper channel layer in the vertical direction so that the source electrode and the drain electrode are electrically connected to the lower channel layer.

In accordance with some embodiments of the present disclosure, a semiconductor structure of the present disclosure includes a gate electrode, a gate dielectric, a channel unit, a source electrode and a drain electrode. The channel unit is insulated from the gate electrode by the gate dielectric. The channel unit includes a lower channel layer and an upper channel layer that is in contact with the lower channel layer in the vertical direction. The lower channel layer has a first composition which is uniform along a vertical direction. The upper channel layer has a second composition which is different from the first composition and which is uniform along the vertical direction. A band gap of the upper channel layer is greater than a band gap of the lower channel layer.

In accordance with some embodiments of the present disclosure, the channel unit further includes a protective channel layer that is disposed between the lower channel layer and the gate dielectric, and that has a band gap greater than the band gap of the lower channel layer.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a gate electrode;
forming a gate dielectric;
forming a channel unit on the gate dielectric opposite to the gate electrode, the channel unit including:
a lower channel layer including a first composition that is uniform throughout the lower channel layer, the lower channel layer having a first band gap; and
an upper channel layer including a second composition that is different from the first composition and that is uniform throughout the upper channel layer, the upper channel layer having a second band gap greater than the first band gap; and
forming a source electrode and a drain electrode that are electrically connected to the lower channel layer, and that are spaced apart from each other.

2. The method according to claim 1, wherein the first composition includes a first metal oxide that has a band gap not greater than 4 eV.

3. The method according to claim 2, wherein the second composition is free of the first metal oxide.

4. The method according to claim 1, wherein the second composition includes a second metal oxide with a band gap greater than 4 eV.

5. The method according to claim 1, wherein forming the channel unit further includes forming a protective channel layer on the gate dielectric prior to forming the lower channel layer and the upper channel layer, the protective channel layer including a third composition that is different from the first composition and that is uniform throughout the protective channel layer.

6. The method according to claim 5, wherein the third composition includes a third metal oxide with a band gap greater than 4 eV.

7. The method according to claim 6, wherein a thickness of the protective channel layer is smaller than a thickness of the lower channel layer.

8. The method according to claim 7, wherein the thickness of the protective channel layer is greater than 0.5 nm.

9. The method according to claim 1, wherein the second band gap is greater than the first band gap by not greater than 0.5 eV.

10. The method according to claim 1, wherein a thickness of the upper channel layer is greater than a thickness of the lower channel layer.

11. A method for manufacturing a semiconductor structure, comprising:
forming a gate electrode;
forming a gate dielectric;
forming a channel unit, the channel unit including a lower channel layer and an upper channel layer that are sequentially formed on the gate dielectric along a vertical direction in a manner that:
the lower channel layer has a first composition which is uniform along the vertical direction,
the upper channel layer has a second composition which is different from the first composition and which is uniform along the vertical direction, and
a band gap of the upper channel layer is greater than a band gap of the lower channel layer; and
forming a source electrode and a drain electrode that are electrically connected to the lower channel layer, and that are spaced apart from each other.

12. The method according to claim 11, wherein forming the channel unit further includes forming a protective channel layer on the gate dielectric opposite to the gate electrode prior to forming the lower channel layer and the upper channel layer, the protective channel layer having a third composition which is different from the first composition and which is uniform along the vertical direction, a band gap of the protective channel layer being greater than the band gap of the lower channel layer.

13. The method according to claim 12, wherein a band gap difference between the upper channel layer and the lower channel layer is not greater than 0.5 eV, and a band gap difference between the lower channel layer and the protective channel layer is not greater than 0.5 eV.

14. The method according to claim 12, wherein a thickness of the upper channel layer is greater than a thickness of the lower channel layer, and the thickness of the lower channel layer is greater than a thickness of the protective channel layer.

15. The method according to claim 11, further comprising forming a dielectric cap layer on the channel unit opposite to the gate dielectric.

16. The method according to claim 15, wherein an oxygen treatment is performed during forming the dielectric cap layer.

17. The method according to claim 15, wherein a plasma treatment is performed during forming the dielectric cap layer.

18. The method according to claim 15, wherein each of the source electrode and the drain electrode is formed to extend through the dielectric cap layer and the upper channel layer in the vertical direction so that the source electrode and the drain electrode are electrically connected to the lower channel layer.

19. A semiconductor structure, comprising:
a gate electrode;
a gate dielectric;
a channel unit that is insulated from the gate electrode by the gate dielectric, the channel unit including:
a lower channel layer having a first composition which is uniform along a vertical direction, and
an upper channel layer that is in contact with the lower channel layer in the vertical direction, the upper channel layer having a second composition which is different from the first composition and which is uniform along the vertical direction, a band gap of the upper channel layer being greater than a band gap of the lower channel layer; and
a source electrode and a drain electrode that are electrically connected to the lower channel layer, and that are spaced apart from each other.

20. The semiconductor structure according to claim 19, wherein the channel unit further includes a protective channel layer that is disposed between the lower channel layer and the gate dielectric, and that has a band gap greater than the band gap of the lower channel layer.
